(19) United States
(12) Patent Application Publication
(10) Pub. No.: US 2023/0082384 A1
(43) Pub. Date: Mar. 16, 2023

(54) SUBSTRATE PROCESSING APPARATUS AND METHOD OF MANUFACTURING SEMICONDUCTOR CHIP USING THE SAME

(71) Applicant: Samsung Electronics Co., Ltd., Suwon-si (KR)

(72) Inventors: Junho Yoon, Anyang-si (KR); Yeongbeom Ko, Cheonan-si (KR); Hwayoung Lee, Hwaseong-si (KR); Junggeun Shin, Cheonan-si (KR); Hyunsu Sim, Cheonan-si (KR); Kwangyong Lee, Anyang-si (KR); Jongho Lee, Hwaseong-si (KR)

(21) Appl. No.: 17/730,993

(22) Filed: Apr. 27, 2022

(30) Foreign Application Priority Data
Sep. 13, 2021 (KR) 10-2021-0122070

(51) Int. Cl. H01L 21/67; H01L 21/683; B23K 26/53

(52) U.S. Cl. CPC H01L 21/67092; H01L 21/6838; B23K 26/53; B23K 2103/56

(57) ABSTRACT

A substrate processing apparatus includes a chuck table including a mounting table having a mounting surface on which a substrate is mounted, wherein the mounting surface is a curved surface; and a laser supply head configured to irradiate the substrate attached to the mounting table with a laser beam.

### CROSS-REFERENCE TO RELATED APPLICATION

This application is based on and claims priority under 35 U.S.C. § 119 to Korean Patent Application No. 10-2021-0122070, filed on Sep. 13, 2021, in the Korean Intellectual Property Office, the disclosure of which is incorporated by reference herein in its entirety.

### BACKGROUND

The inventive concept relates to a substrate processing apparatus and a method of manufacturing a semiconductor chip using the same, and more particularly, to a substrate processing apparatus configured to cut the substrate using a laser beam, and a method of manufacturing a semiconductor chip using the substrate processing apparatus.

After forming integrated circuits on an active surface of a semiconductor substrate, the semiconductor substrate is cut, and the integrated circuits are separated into a plurality of semiconductor chips. In general, the semiconductor substrate is mechanically cut using a sawing blade. When the semiconductor substrate is mechanically cut in this way, there is a high possibility that defects such as chipping may occur in the semiconductor chip. In recent years, a method of cutting a substrate using a laser beam has been studied as a method of reducing physical damage to the semiconductor chip, such as chipping.

### SUMMARY

The inventive concept provides a substrate processing apparatus configured to cut a substrate using a laser beam and a method of manufacturing a semiconductor chip using the substrate processing apparatus.

Objectives to be solved by the technical idea of the inventive concept are not limited to the above-mentioned objectives, and other objectives that are not stated may be clearly understood by those skilled in the art from the following description.

According to an aspect of the inventive concept, there is provided a substrate processing apparatus including a chuck table including a mounting table having a mounting surface configured such that a substrate is mounted on the mounting surface, the mounting surface is a curved surface, and a laser supply head configured to irradiate the substrate mounted on the mounting table with a laser beam.

According to another aspect of the inventive concept, there is provided a substrate processing apparatus configured to perform a stealth dicing process on a substrate, the substrate processing apparatus including a chuck table including a mounting table having a mounting surface configured such that the substrate is vacuum adsorbed on the mounting surface, wherein the mounting surface has a curved surface and configured such that the substrate is vacuum adsorbed on the mounting surface so that the substrate is modified to have a curvature corresponding to a curvature of the mounting surface, and a laser supply head configured to irradiate the substrate vacuum adsorbed to the mounting table with a laser beam.

According to another aspect of the inventive concept, there is provided a substrate processing apparatus configured to perform a stealth dicing process on a substrate, the substrate processing method including a chuck table including a mounting table having a table surface configured such that the substrate is vacuum adsorbed on the mounting surface and vacuum channels extending from the mounting surface and a vacuum pump connected to the vacuum channels of the mounting table, a stage configured to move the mounting table, and a laser supply head configured to irradiate the substrate attached to the mounting table with a laser beam, wherein the mounting surface of the mounting table includes a concave curved surface, the chuck table is configured to modify the substrate so that the substrate has a curvature corresponding to a curvature of the mounting surface of the mounting table, and the laser supply head irradiates a focusing point in the substrate modified by the chuck table with the laser beam.

According to another aspect of the inventive concept, there is provided a method of manufacturing a semiconductor chip, the method including preparing a substrate, the substrate including integrated circuit regions and a cutting region in which the integrated circuit regions are separated from each other, and cutting the substrate along the cutting region to separate the substrate into semiconductor chips, wherein the cutting of the substrate includes modifying the substrate so that one surface of the substrate includes a curved surface, and forming a modification layer in the substrate by irradiating the modified substrate with a laser beam.

### BRIEF DESCRIPTION OF THE DRAWINGS

Embodiments of the inventive concept will be more clearly understood from the following detailed description taken in conjunction with the accompanying drawings in which:

FIG. 1 is a view illustrating a configuration of a substrate processing apparatus according to example embodiments;

FIG. 2 is a plan view illustrating a mounting table of a chuck table of FIG. 1;

FIG. 3 is a view illustrating a configuration of a laser supply head of FIG. 1;

FIG. 4 is a flowchart illustrating a method of manufacturing a semiconductor chip, according to example embodiments;

FIGS. 5A through 5D are views illustrating a method of manufacturing a semiconductor chip, according to example embodiments;

FIG. 6 is an enlarged view illustrating a substrate within a region VI of FIG. 5D;

FIGS. 7A and 7B are views illustrating a configuration of a substrate processing apparatus according to example embodiments; and

FIGS. 8A and 8B are views illustrating a configuration of a substrate processing apparatus according to example embodiments.

### DETAILED DESCRIPTION OF THE EMBODIMENTS

Hereinafter, example embodiments of the inventive concept will be described in detail with reference to the accompanying drawings. For the same components on the drawing, the same reference numerals are used, and redundant description thereof will be omitted.

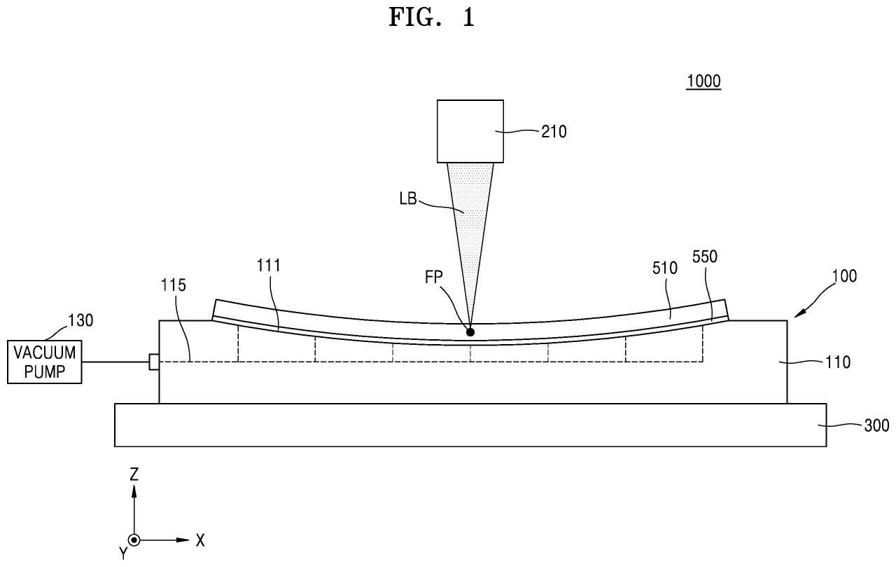

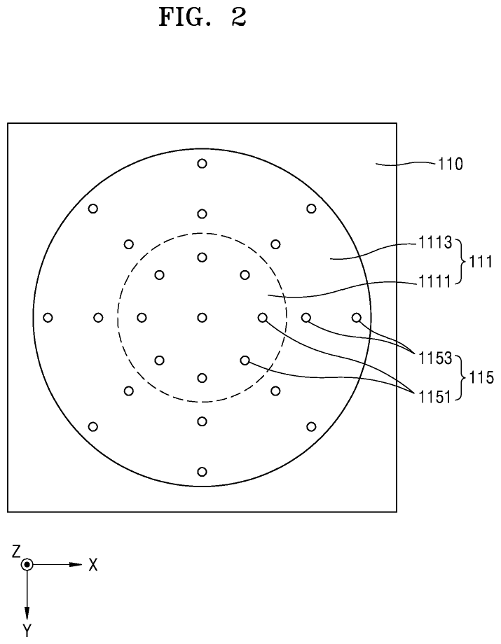

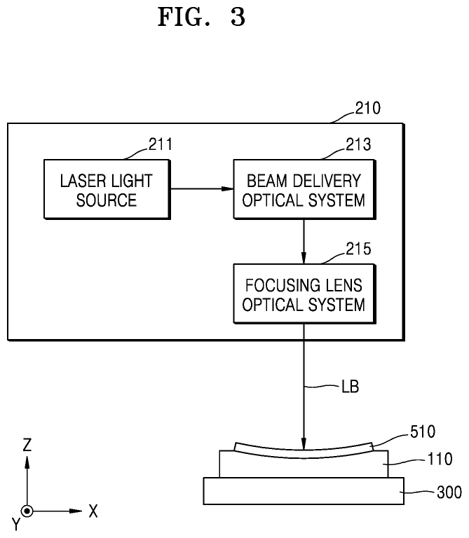

FIG. 1 is a view illustrating a configuration of a substrate processing apparatus 1000 according to example embodiments. FIG. 2 is a plan view illustrating a mounting table 110 of a chuck table 100 of FIG. 1. FIG. 3 is a view illustrating a configuration of a laser supply head 210 of FIG. 1.

Referring to FIGS. 1 through 3, the substrate processing apparatus 1000 may be configured to perform a dicing process of separating a substrate 510, which is a work piece, into single chip unit structures (e.g., a plurality of chips/dice). In example embodiments, the substrate processing apparatus 1000 may be configured to perform a laser dicing process for cutting the substrate 510 using a laser beam LB. In example embodiments, the substrate processing apparatus 1000 may be configured to perform a stealth dicing process for focusing the laser beam LB in the substrate 510 to form a modification layer in the substrate 510 and cutting the substrate 510 with a crack derived from the modification layer.

The substrate processing apparatus 1000 may include the chuck table 100 for supporting the substrate 510, the laser supply head 210 for outputting the laser beam LB for processing the substrate 510, and a stage 300.

The chuck table 100 may include a mounting table 110 including a mounting surface 111 on which the substrate 510 is mounted. The mounting surface 111 of the mounting table 110 may vertically overlap the substrate 510 and/or may be in contact with the substrate 510 when the substrate 510 is mounted on the mounting table 110. The mounting surface 111 of the mounting table 110 may have a shape corresponding to the shape of the substrate 510. For example, the mounting surface 111 may have a circular shape in a plan view. The substrate 510 may be entirely attached to the mounting surface 111 of the mounting table 110. For example, a central portion and an outer portion of the substrate 510 may be both attached to the mounting surface 111 of the mounting table 110.

When the substrate 510 is seated on the mounting surface 111 of the mounting table 110, the chuck table 100 may attach the substrate 510 to the mounting surface 111 of the mounting table 110 by applying an external force to the substrate 510. The chuck table 100 may be configured to perform a chucking operation for applying an external force to the substrate 510 so that the substrate 510 may be attached to the mounting table 110, or a dechucking operation for releasing or terminating the external force on the substrate 510 so that the substrate 510 may be separated from the mounting table 110. For example, the chucking operation may be a substrate attaching operation and the dechucking operation may be a substrate releasing operation.

In example embodiments, the chuck table 100 may be configured to vacuum adsorb the substrate 510. For example, vacuum adsorb or vacuum adsorption may be an attaching operation using vacuum pressure. The mounting surface 111 of the mounting table 110 may be a surface on which the substrate 510 is vacuum adsorbed, and the mounting table 110 may include vacuum channels 115 extending into the mounting table 110 from the mounting surface 111. The vacuum channels 115 may be exposed on/through the mounting surface 111. The vacuum channels 115 may be generally evenly distributed on the mounting surface 111.

In example embodiments, the mounting table 110 may include a first vacuum channel 1151 provided to a central portion 1111 of the mounting surface 111, and a second vacuum channel 1153 provided to an outer portion 1113 of the mounting surface 111 surrounding the central portion 111 of the mounting surface 111 in a plan view. One or more first vacuum channels 1151 may be provided in the central portion 1111 of the mounting surface 111, and one or more second vacuum channels 1153 may be provided in the outer portion 1113 of the mounting surface 111. The first vacuum channel 1151 may extend from the central portion 1111 of the mounting surface 111 toward inside of the mounting table 110, and the second vacuum channel 1153 may extend from the outer portion 1113 of the mounting surface 111 toward inside of the mounting table 110. In this case, the central portion of the substrate 510 may be vacuum adsorbed to the mounting table 110 by an adsorption force applied through the first vacuum channel 1151 provided in the central portion 1111 of the mounting surface 111, and the outer portion of the substrate 510 may be vacuum adsorbed to the mounting table 110 by an adsorption force applied through the second vacuum channel 1153 provided in the outer portion 1113 of the mounting surface 111.

The chuck table 100 may include a vacuum pump 130 connected to the vacuum channels 115 of the mounting table 110. The vacuum pump 130 may apply a vacuum pressure to the vacuum channels 115 of the mounting table 110 so that the substrate 510 may be vacuum adsorbed to the mounting surface 111 of the mounting table 110. For example, when the vacuum pump 130 applies the vacuum pressure to the vacuum channels 115 of the mounting table 110, a lower pressure than a peripheral pressure may be formed on one surface of the substrate 510 facing the mounting surface 111 of the mounting table 110 so that the substrate 510 may be vacuum adsorbed to the mounting table 110. The vacuum pump 130 may release or terminate the vacuum pressure to the vacuum channels 115 of the mounting table 110 so that the substrate 510 may be separated from the mounting table 110.

In other example embodiments, the chuck table 100 may include an electrostatic chuck configured to fix the substrate 510 using an electrostatic force. Alternatively, the chuck table 100 may be configured to fix the substrate 510 using a mechanical method.

The chuck table 100 may be configured to forcibly modify (or forcibly deform) the shape of the substrate 510 attached to the mounting surface 111 of the mounting table 110. For example, the substrate 510 originally has a flat plate shape, and the chuck table 100 may deform or modify the substrate 510 so that the substrate 510 has a bent portion. For example, the substrate 510 may be a flat plate.

In example embodiments, the chuck table 100 may be configured to modify the substrate 510 so that the substrate 510 may be modified into a shape corresponding to the mounting surface 111. In example embodiments, the chuck table 100 may be configured to modify the substrate 510 so that top and bottom surfaces of the substrate 510 may have curved surfaces, respectively. In example embodiments, the chuck table 100 may be configured to modify the substrate t10 so that the top surface of the substrate 510 may be modified into a concave shape, e.g., the center of the substrate 510 may protrude downwards with respect to edges of the substrate 510. In example embodiments, the chuck table 100 may be configured to modify the substrate t10 so that the top surface of the substrate 510 may be modified into a convex shape, e.g., the center of the substrate 510 may protrude upwards with respect to the edges of the substrate 510.

In example embodiments, the mounting surface 111 of the mounting table 110 may be a non-flat surface. For example, in a cross-sectional view of the mounting table 110, the mounting surface 111 of the mounting table 110 may include a curved surface. For example, in the cross-sectional view of the mounting table 110, the mounting surface 111 of the mounting table 110 may have a curvature or a curvilinear profile. In this case, the chuck table 100 may be configured to modify the substrate 510 to have a curvature corresponding to the curvature of the mounting surface 111 of the mounting table 110 by applying an external force to the substrate 510. For example, when the substrate 510 transported from the outside is seated on the mounting surface 111 of the mounting table 110, the chuck table 100 may be configured to vacuum adsorb the substrate 510 so that the substrate 510 may be in close contact with the mounting surface 111 of the mounting table 110. As the substrate 510 is vacuum adsorbed to the mounting surface 111 of the mounting table 110, the substrate 510 (or the top and bottom surfaces of the substrate 510) may be modified into a shape corresponding to the shape of the mounting surface 111 of the mounting table 110.

The mounting surface 111 of the mounting table 110 may have a concave shape. In the cross-sectional view of the mounting table 110, the center of the mounting surface 111 of the mounting table 110 may be located at a lower level than the edge of the mounting surface 111 of the mounting table 110. Various dimensions of the mounting surface 111, for example, the diameter of the mounting surface 111, a height difference in a vertical direction (Z-direction) between the center of the mounting surface 111 and the edge of the mounting surface 111, the curvature of the mounting surface 111, and the like may be appropriately adjusted depending on the size of the substrate 510, the target modification of the substrate 510, and the like. For example, the height difference in the vertical direction (Z-direction) between the center of the mounting surface 111 and the edge of the mounting surface 111 may be between several tens of micrometers and several millimeters. In example embodiments, the height difference in the vertical direction (Z-direction) between the center of the mounting surface 111 and the edge of the mounting surface 111 may be between about 25 μm and about 800 μm, between about 35 μm and about 600 μm, or between about 50 μm and about 400 μm. In example embodiments, the radius of the mounting surface 111, e.g., a distance in a horizontal direction (X-direction and/or Y-direction) between the center of the mounting surface 111 and the edge of the mounting surface 111, may be at a level similar to the radius of the substrate 510 mounted on the mounting surface 111. For example, the radius of the mounting surface 111 may be between about 15 mm and about 200 mm.

Spatially relative terms, such as “beneath,” “below,” “lower,” “above,” “upper” and the like, may be used herein for ease of description to describe positional relationships. It will be understood that the spatially relative terms encompass different orientations of the device in addition to the orientation depicted in the figures.

The chuck table 100 may be configured to vacuum adsorb the substrate 510 so that the substrate 510 may be in close contact with the mounting surface 111 of the mounting table 110, thereby modifying the substrate 510 into a concave form. The mounting surface 111 of the mounting table 110 may entirely have a concave shape, or only a portion thereof may have a concave shape.

As shown in FIG. 1, the mounting surface 111 of the mounting table 110 may have a concave-shaped surface. In the cross-sectional view of the mounting table 110, the center of the mounting surface 111 of the mounting table 110 may be located at a lower level than the edge of the mounting surface 111 of the mounting table 110, and the mounting surface 111 of the mounting table 110 may have a curvilinear profile. In this case, as the substrate 510 is vacuum adsorbed to the mounting surface 111 of the mounting table 110, the substrate 510 may be modified into a shape substantially the same as or similar to the curvature of the mounting surface 111 of the mounting table 110.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

In example embodiments, the mounting surface 111 of the mounting table 110 may entirely have a concave-shaped surface. For example, in the cross-sectional view of the mounting table 110, the profile of the mounting surface 111 of the mounting table 110 may have a curvilinear profile from one edge to another edge of the mounting surface 111 of the mounting table 110.

In example embodiments, only a portion of the mounting surface 111 of the mounting table 110 may have a concave-shaped surface. For example, the central portion 1111 of the mounting surface 111 of the mounting table 110 may be a concave-shaped surface, and an outer portion surrounding the central portion 1111 of the mounting surface 111 of the mounting table 110 may be a plane. In this case, in the cross-sectional view of the mounting table 110, the central portion 1111 of the mounting surface 111 of the mounting surface 110 may have a curvilinear profile, and the outer portion 1113 of the mounting surface 111 of the mounting surface 111 may have a straight line-shaped profile.

In example embodiments, the mounting surface 111 of the mounting table 110 may have a constant curvature. For example, the curvature of the central portion 1111 of the mounting surface 111 of the mounting table 110 may be substantially the same as or similar to the curvature of the outer portion 1113 of the mounting surface 111 of the mounting table 110.

In example embodiments, the curvature of the mounting surface 111 of the mounting table 110 may be different for each region. For example, the curvature of the central portion 1111 of the mounting surface 111 of the mounting table 110 may be different from the curvature of the outer portion 1113 of the mounting surface 111 of the mounting table 110. For example, the curvature of the central portion 1111 of the mounting surface 111 of the mounting surface 110 may be greater than the curvature of the outer portion 1113 of the mounting surface 111 of the mounting surface 110.

The laser supply head 210 may be disposed above the mounting table 110 and may be configured to irradiate the laser beam LB in a downward direction (e.g., Z-direction) toward the substrate 510 mounted on the mounting table 110. For example, the laser supply head 210 may irradiate the substrate 510 with the laser beam LB. The laser supply head 210 may include at least one laser light source 211, a beam delivery optical system 213, and a focusing lens optical system 215.

At least one laser light source 211 may generate and output the laser beam LB. At least one laser light source 211 may include one light source or a plurality of light sources. At least one laser light source 211 may be configured to generate a laser beam LB having a characteristic suitable for processing the substrate 510, which is a work piece. For example, depending on the material and thickness of the substrate 510, the wavelength, the pulse width, and the power of the laser beam LB output from the at least one laser light source 211 may be adjusted. In example embodiments, at least one laser light source 211 may output a laser beam LB having a wavelength band of infrared rays.

The beam delivery optical system 213 may deliver the laser beam LB output from at least one laser light source 211 to the focusing lens optical system 215. The beam delivery optical system 213 may be free space optics. However, example embodiments are not limited thereto. The beam delivery optical system 213 may include a variety of optical elements such as a polarizer, a lens, a reflector, a prism, a splitter, and the like.

The focusing lens optical system 215 may focus the laser beam LB on a focusing point FP that is a set position in the substrate 510. For example, the focusing point FP may be positioned inside the substrate 510. The focusing lens optical system 215 may adjust the position of the focusing point FP of the laser beam LB. For example, the focusing lens optical system 215 may adjust the focusing point FP of the laser beam LB so that the laser beam LB may be focused in a target position in the substrate 510. The focusing lens optical system 215 may include a single lens or a plurality of lenses.

The stage 300 may be connected to the chuck table 100. The stage 300 may include an actuator for moving the mounting table 110 of the chuck table 100. In example embodiments, the stage 300 may be configured to linearly move the mounting table 110 in a horizontal direction (X-direction and/or Y-direction). In example embodiments, the stage 300 may be configured to linearly move the mounting table 110 in a vertical direction (Z-direction). In example embodiments, the stage 300 may rotate the mounting table 110. For example, the stage 300 may be configured to rotate the mounting table 110 on a rotary axis parallel to a vertical direction (Z-direction). For example, the mounting table 110 may rotate about an axis extending in the vertical direction, e.g., by an operation of the actuator. For example, the rotation axis of the mounting table 110 may pass through the center of the mounting table 110.

In example embodiments, the stage 300 may tilt the mounting table 110. For example, the tilting movement of the mounting table 110 by the stage 300 may include rotating the mounting table 110 on a rotary axis parallel to the horizontal direction (X-direction and/or Y-direction). The stage 300 may be configured to tilt the mounting table 110 to adjust the incident angle of the laser beam LB for the mounting surface 111 of the mounting table 110 or the incident angle of the laser beam LB for the surface of the substrate 510. For example, the stage 300 may be configured to tilt the mounting table 110 so that the incident angle of the laser beam LB for the mounting surface 111 of the mounting table 110 may be a predetermined reference angle. For example, the stage 300 may be configured to tilt the mounting table 110 so that the incident angle of the laser beam LB for the surface of the substrate 510 may be a predetermined reference angle.

The substrate processing apparatus 1000 may include a controller for controlling the entire process using the substrate processing apparatus 1000. The operation of components constituting the substrate processing apparatus 1000 may be controlled by the controller. The controller may be implemented with hardware, firmware, software, or an arbitrary combination thereof. For example, the controller may be a computing device, such as a workstation computer, a desktop computer, a laptop computer, a tablet computer, and the like. For example, the controller may include a memory device, such as Read Only Memory (ROM), Random Access Memory (RAM), or the like, in which various programming instructions are stored, and a processor, such as a microprocessor configured to process the programming instructions stored in the memory device and signals provided from the outside, a Central Processing Unit (CPU), a Graphics Processing Unit (GPU), and the like. Also, the controller may include a receiver and a transmitter for receiving and transmitting an electrical signal.

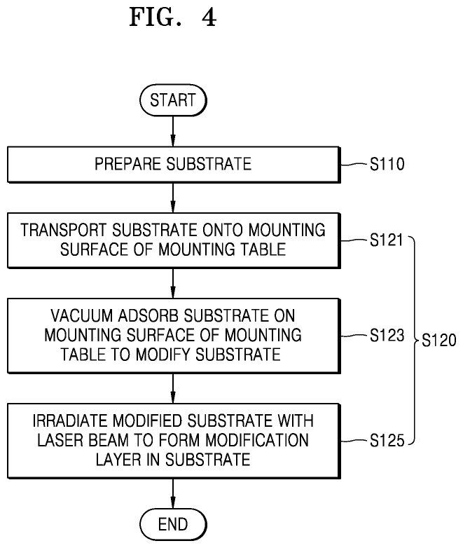

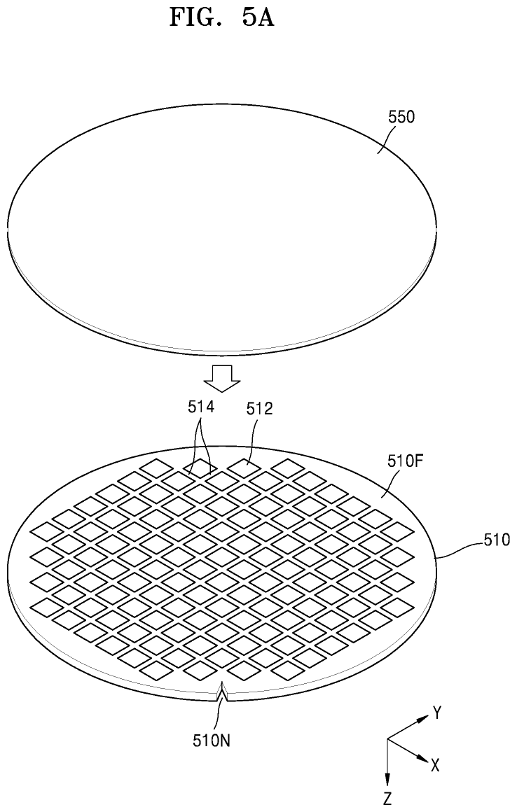

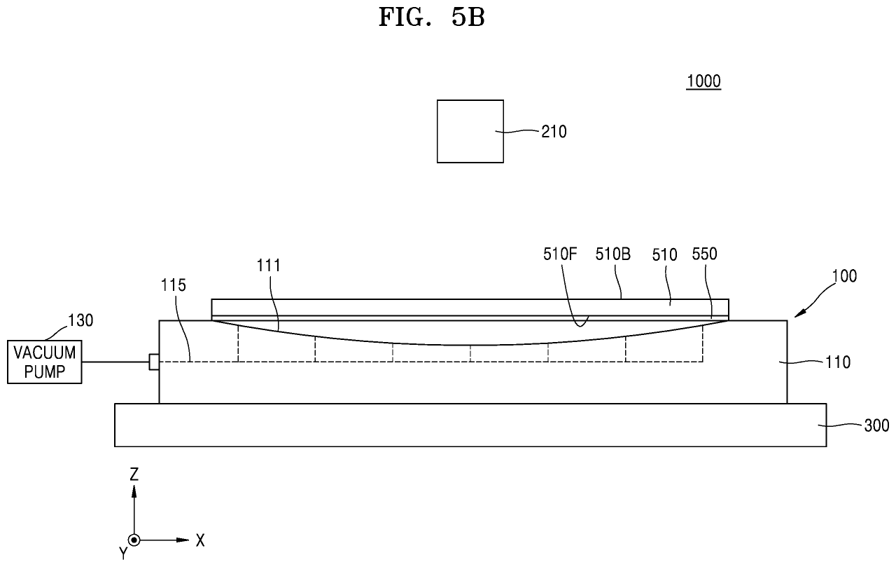

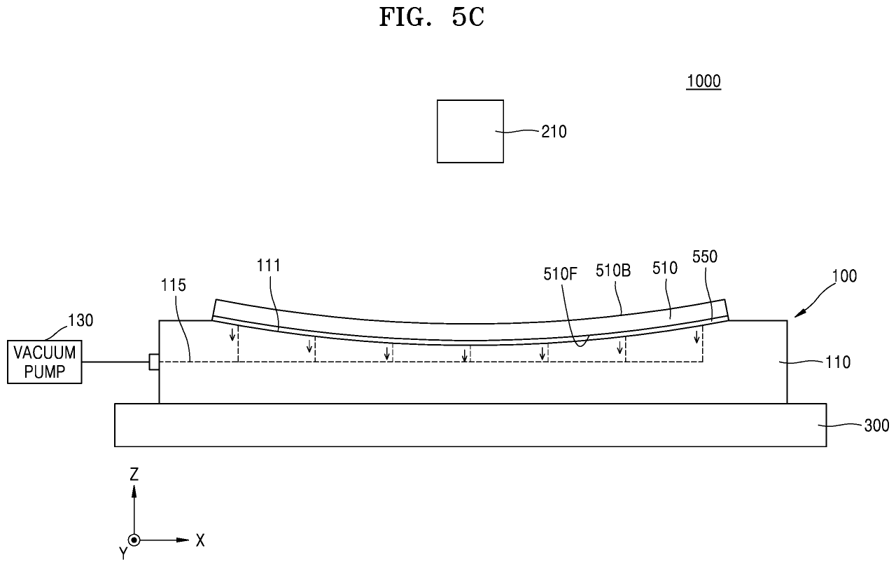

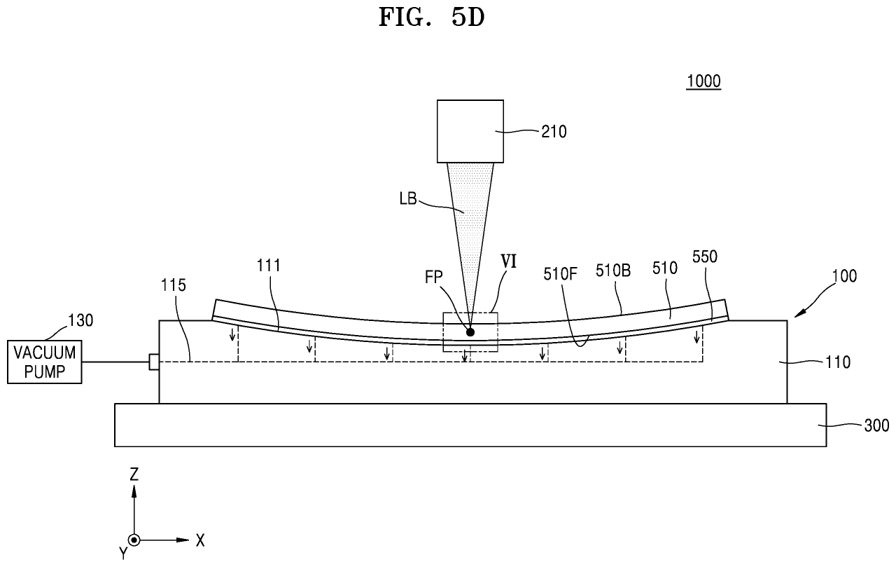

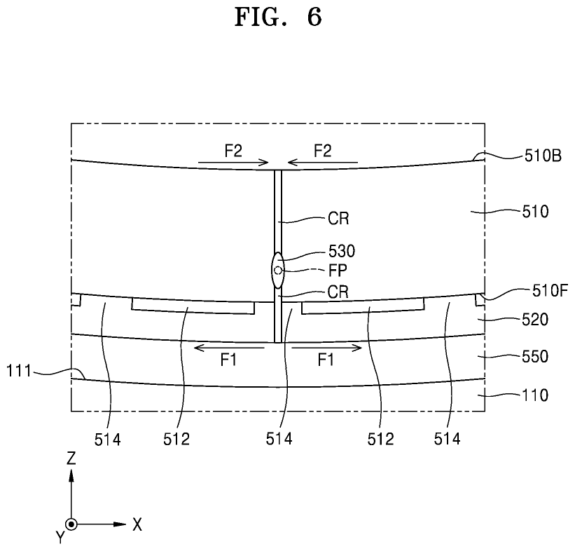

FIG. 4 is a flowchart illustrating a method of manufacturing a semiconductor chip, according to example embodiments. FIGS. 5A through 5D are views illustrating a method of manufacturing a semiconductor chip/device, according to example embodiments. FIG. 6 is an enlarged view illustrating the substrate 510 within a region VI of FIG. 5D.

Hereinafter, the method of manufacturing a semiconductor chip including a substrate processing method using the substrate processing apparatus 1000 illustrated in FIG. 1 will be described with reference to FIGS. 4, 5A through 5D, and 6.

Referring to FIG. 5A, a substrate 510 including integrated circuit regions 512 and a cutting region 514 in which the integrated circuit regions 512 are separated from each other, may be prepared (S110).

The substrate 510 may be a semiconductor substrate. The substrate 510 may be a wafer and may have a circular shape, e.g., in a plan view. The substrate 510 may have a notch 510N used as a reference indication for the alignment of the substrate 510. The substrate 510 may include or be formed of silicon. Alternatively, the substrate 510 may include or be formed of a semiconductor element such as germanium, or a compound semiconductor such as silicon carbide (SiC), gallium arsenide (GaAs), indium arsenide (InAs), and indium phosphide (InP). Alternatively, the substrate 510 may have a silicon on insulator (SOI) structure. In some embodiments, the substrate 510 may include an impurity-doped well or an impurity-doped structure, which is a conductive region. Also, the substrate 510 may have various isolation structures such as a shallow trench isolation (STI) structure and the like. Here, it is assumed that the substrate 510 has a diameter of approximately 12 inches, and the case where silicon wafer is used, will be described. However, it will be understood by those skilled in the art that the substrate 510 having a diameter less than or greater than 12 inches may be used and the substrate 510 including or formed of a different material than silicon may be used.

The substrate 510 may include an active surface 510F and an inactive surface 510B opposite to each other. The substrate 510 may include integrated circuit regions 512 and a cutting region 514 in which the integrated circuit regions 512 are separated from each other. The cutting region 514 may be referred to as a scribe lane. The cutting region 514 may extend in a first horizontal direction (e.g., X-direction) and/or a second horizontal direction (e.g., Y-direction). The cutting region 514 may have a straight lane shape having a constant width. Each of the integrated circuit regions 512 may be surrounded by the cutting region 514, e.g., in a plan view. As described below, as the substrate 510 and various kinds of material layers formed on the substrate 510 are cut by a cutting process performed along the cutting region 514, the integrated circuit regions 512 may be separated from each other into a plurality of semiconductor chips.

A semiconductor element layer (see 520 of FIG. 6) may be formed on the active surface 510F of the substrate 510. The semiconductor element layer 520 may include an insulating layer and/or a conductive layer provided on the active surface 510F of the substrate 510. Also, the semiconductor element layer 520 may include a semiconductor element and a metal interconnect structure.

The semiconductor element of the semiconductor element layer 520 may include a memory device and/or a logic device.

The memory device may constitute or may be a volatile memory device or a non-volatile memory device. The non-volatile memory device may include or may be an existing volatile memory device, such as dynamic random access memory (DRAM), static RAM (SRAM), thyristor RAM (TRAM), zero capacitor RAM (ZRAM), or Twin Transistor RAM (TTRAM), and/or a volatile memory device currently being developed. In certain embodiments, the non-volatile memory device may include or may be an existing non-volatile memory device, such as flash memory, magnetic RAM (MRAM), spin-transfer torque (STT-MRAM), ferroelectric RAM (FRAM), phase change RAM (PRAM), resistive RAM (RRAIVI), nanotube RAM, polymer RAM, nano floating gate memory, holographic memory, molecular electronics memory, or insulator resistance change memory, and/or a non-volatile memory device currently being developed.

The logic device may be implemented with, for example, as a microprocessor, a graphics processor, a signal processor, a network processor, an audio codec, a video codec, an application processor, or a system on chip, and the like. However, example embodiments are not limited thereto. The microprocessor may include, for example, a single core or multi-cores.

In an example embodiment, the substrate 510 may refer to the substrate 510 itself, or a stack structure including the substrate 510 and a material layer formed on the surface of the substrate 510, e.g., depending on the context. For example, the substrate 510 may include the substrate 510 itself, and/or a semiconductor element layer 520 formed on the active surface 510F of the substrate 510. Further, “the surface of the substrate 510” may refer to the exposed surface of the substrate 510 itself, or the exposed surface of the material layer formed on the substrate 510, e.g., depending on the context.

A protective sheet 550 may be attached to the active surface 510F of the substrate 510. The protective sheet 550 may cover the semiconductor element layer 520 and may protect the integrated circuit regions 512 while the dicing process is performed on the substrate 510. The protective sheet 550 may be, for example, a polyvinylchloride (PVC)-based polymer sheet and may be attached to the substrate 510 by an acryl resin-based adhesive. The acryl resin-based adhesive may have a thickness of about 2 μm to about 10 μm, and the protective sheet 550 may have a thickness of about 60 μm to about 200 μm. The protective sheet 550 may have a circular shape having a diameter substantially the same as the diameter of the substrate 510.

After preparing the substrate 510, the substrate 510 may be cut along the cutting region 514 of the substrate 510 so that the substrate 510 may be separated into semiconductor chips (S120). For example, the dicing process on the substrate 510 may be performed to separate the substrate 510 into chips. Hereinafter, a method of cutting the substrate 510 through a stealth dicing process on the substrate 510 is illustrated.

Referring to FIG. 5B, the substrate 510 provided from the outside may be transported to the mounting surface 111 of the mounting table 110 (S121). The substrate 510 may be located on the mounting table 110 so that the active surface 510F of the substrate 510 may face the mounting surface 111 of the mounting table 110. The protective sheet 550 may be located between the substrate 510 and the mounting surface 111 of the mounting table 110. Because the mounting surface 111 of the mounting table 110 has a concave shape, a space may be formed between the substrate 510 and the mounting surface 111 of the mounting table 110. For example, when the substrate 510 is disposed on the mounting table 110, there may be a gap between the substrate 510 and the mounting table 110, e.g., between the mounting surface 111 and the active surface 510F, and/or between the mounting surface 111 and a surface of the protective sheet 550 facing the mounting surface 111. For example, distances of the gap between the substrate 510 and the mounting table 110 vary depending on positions. For example, a gap between the substrate 510 and the mounting table 110 may be greater at a center of the substrate 510 than an edge of the substrate 510. For example, the gaps between the substrate 510 and the mounting table 110 may be distances between the substrate 510 and the mounting table 110 in the vertical direction.

Referring to FIG. 5C, the chuck table 100 may be configured to vacuum adsorb the substrate 510 to the mounting surface 111 of the mounting table 110 to modify the substrate 510 (S123).

The chuck table 100 may be configured to vacuum adsorb the substrate 510 to the mounting surface 111 by applying a vacuum pressure to the vacuum channels 115. The substrate 510 may be attached to the mounting surface 111 by an adsorption force applied through the vacuum channels 115 and may be forcibly modified/deformed into a shape corresponding to the shape of the mounting surface 111. For example, the substrate 510 may be modified so that the center of the substrate 510 protrudes downwards with respect to edges thereof.

Referring to FIGS. 5D and 6, the modified/deformed substrate 510 may be irradiated with a laser beam LB to form a modification layer (e.g., a defect region) 530 in the substrate 510 (S125).

The laser supply head 210 may be configured to irradiate the focusing point FP in the modified/deformed substrate 510 with the laser beam LB while the substrate 510 is modified/deformed by the chuck table 100. For example, a distance between the focusing point FP and the active surface 510F of the substrate 510 may be between about 20 μm and about 120 μm, between about 40 μm and about 100 μm, or between about 60 μm and about 80 μm. The laser supply head 210 may be configured to focus the laser beam LB having a wavelength band capable of transmitting the substrate 510 (i.e., a wavelength band having a low absorption rate for a semiconductor substrate) on the focusing point FP inside the substrate 510. The laser beam LB may be repeatedly emitted with a pulse width persisted (e.g., 1 μs or less) for a very short time. As the focusing point FP inside the substrate 510 is repeatedly irradiated with the laser beam LB, the modification layer 530 may be formed in the vicinity of the focusing point FP inside the substrate 510. The modified layer (e.g., a defect region) 530 may include a high-density defect (e.g., a dislocation) generated by adsorbing the laser beam LB, and a crack CR may propagate into the substrate 510 around the modification layer 530.

In example embodiments, the stage 300 may be configured to move the mounting table 110 so that the irradiation position of the laser beam LB on the substrate 510 may be changed while the laser supply head 210 outputs the laser beam LB. For example, the stage 300 may be configured to move the mounting table 110 in a horizontal direction (X-direction and/or Y-direction) so that the substrate 510 may be irradiated with the laser beam LB along the cutting region 514. In other example embodiments, the laser supply head 210 may move in the horizontal direction (X-direction and/or Y-direction) so that the substrate 510 is irradiated with the laser beam LB along the cutting region 514.

In example embodiments, the focusing point FP of the laser beam LB may be closer to the active surface 510F than the inactive surface 510B of the substrate 510, and the modification layer 530 may also be closer to the active surface 510F than the inactive surface 510B of the substrate 510. In this case, the crack CR initiated from the modification layer 530 may propagate to the semiconductor element layer 520, and the semiconductor element layer 520 may be cut by the crack CR. The integrated circuit regions 512 may be separated from each other by the crack CR, and each of the separated integrated circuit regions 512 may constitute a semiconductor chip.

As shown in FIG. 6, while the substrate 510 is forcibly modified into a concave form, tensile stress F1 may be applied to the lower side/portion of the substrate 510 adjacent to the mounting surface 111 of the mounting table 110, and compressive stress F2 may be applied to the upper side/portion of the substrate 510. The tensile stress F1 may be predominant in the vicinity of the modification layer 530 formed by irradiating the focusing point FP adjacent to the active surface 510F of the substrate 510. The tensile stress F1 may facilitate the formation of the modification layer 530 and may increase the propagation distance of the crack CR initiated from the modification layer 530.

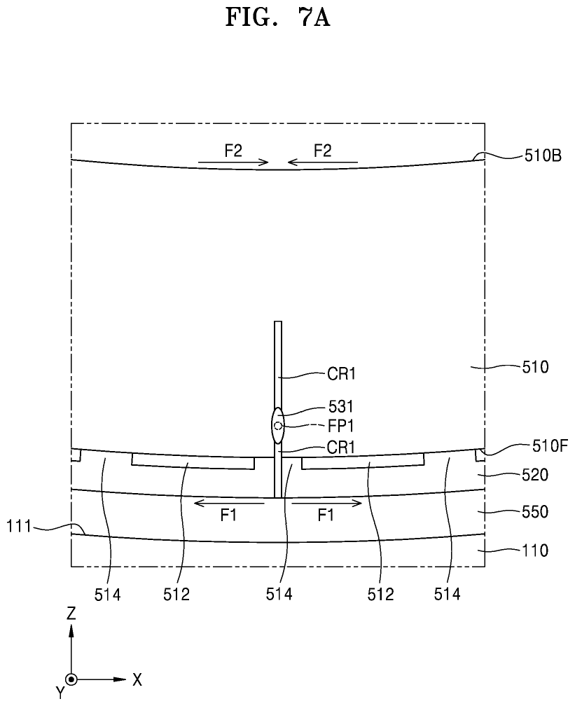

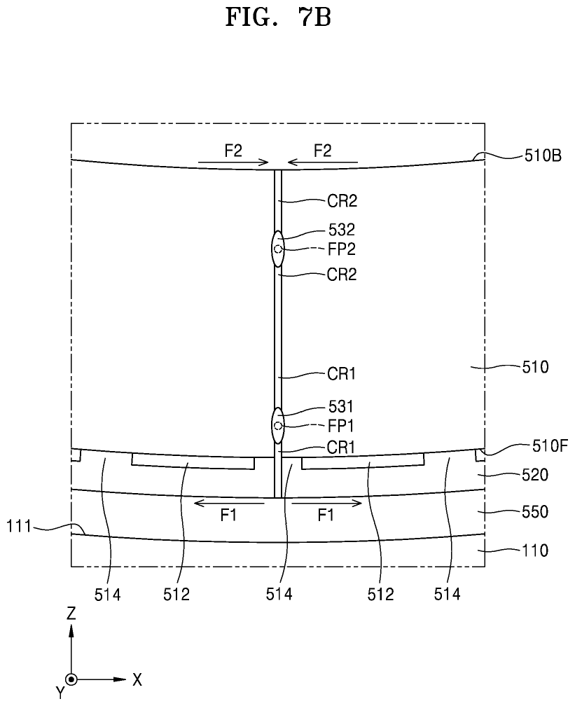

FIGS. 7A and 7B are views illustrating the configuration of a substrate processing apparatus according to example embodiments.

Hereinafter, referring to FIG. 1, FIGS. 7A, and 7B, as one example of a substrate processing method using the substrate processing apparatus 1000 shown in FIG. 1, a method of performing a stealth dicing process on the substrate 510 will be described.

Referring to FIG. 7A, the laser supply head 210 may be configured to perform first laser scanning for scanning the laser beam LB on a first focusing point FP1 in the substrate 510 so as to form a first modification layer 531 in the substrate 510. While first laser scanning is performed, the stage 300 may move the mounting table 110 in a direction (e.g., X-direction and/or Y-direction) perpendicular to the irradiation/emitting direction (e.g., Z-direction) of the laser beam LB so that the irradiation position of the laser beam LB may move along the cutting region 514 of the substrate 510.

At first laser scanning, the laser supply head 210 may be configured to focus the laser beam LB on the first focusing point FP1 in the substrate 510. The first focusing point FP1 may be more adjacent (e.g., closer) to the active surface 510F than the inactive surface 510B of the substrate 510. As the first focusing point FP1 is irradiated with the laser beam LB, the first modification layer 531 may be formed in the first focusing point FP1 and in the vicinity of the first focusing point FP1. Because the irradiation position of the laser beam LB moves in the horizontal direction (e.g., X-direction and/or Y-direction), the first modification layer 531 may also extend continuously or discontinuously in the horizontal direction (e.g., X-direction and/or Y-direction). A first crack CR1 initiated from the first modification layer 531 may propagate in the thickness direction (e.g., Z-direction) of the substrate 510. For example, the first crack CR1 may propagate from the first modification layer 531 in each of downward and upward directions. The semiconductor element layer 520 may be cut by the first crack CR1 propagated from the first modification layer 531 in the downward direction.

Referring to FIG. 7B, the laser supply head 210 may be configured to perform second laser scanning for scanning the laser beam LB on a second focusing point FP2 in the substrate 510 so as to form a second modification layer 532 in the substrate 510. While second laser scanning is performed, the stage 300 may move the mounting table 110 in a direction (e.g., X-direction and/or Y-direction) perpendicular to the irradiation/emitting direction (e.g., Z-direction) of the laser beam LB so that the irradiation position of the laser beam LB may move along the cutting region 514 of the substrate 510.

At second laser scanning, the laser supply head 210 may focus the laser beam LB on the second focusing point FP2 in the substrate 510. The second focusing point FP2 may be a point that is spaced apart from the first focusing point FP1 in a direction receding from the mounting surface 111 of the mounting table 110. For example, a distance in a vertical direction between the second focusing point FP2 and the first focusing point FP1 may be between about 100 μm to about 200 μm. When the first focusing point FP1 is at the first distance from the mounting surface 111 of the mounting table 110, the second focusing point FP2 may be at a second distance from the mounting surface 111 of the mounting table 110, the second distance being greater than the first distance. For example, the first focusing point FP1 may be more adjacent (e.g., closer) to the mounting surface 111 of the mounting table 110 than the second focusing point FP2.

As the second focusing point FP2 is irradiated with the laser beam LB, the second modification layer 532 may be formed in the second focusing point FP2 and in the vicinity of the second focusing point FP2. Because the irradiation position of the laser beam LB moves in the horizontal direction (e.g., X-direction and/or Y-direction), the second modification layer 532 may also extend continuously or discontinuously in the horizontal direction (e.g., X-direction and/or Y-direction). A second crack CR2 initiated from the second modification layer 532 may propagate in the thickness direction (e.g., Z-direction) of the substrate 510. For example, the second crack CR2 may propagate from the second modification layer 532 in each of downward and upward directions. At this time, the second crack CR2 propagated downward from the second modification layer 532 may be connected to the first crack CR1 propagated from the first modification layer 531, and the second crack CR2 extending upwardly from the second modification layer 532 may extend to the inactive surface 510B of the substrate 510. In this case, cutting of the substrate 510 may be completed by the first crack CR1 propagated from the first modification layer 531 and the second crack CR2 propagated from the second modification layer 532.

In FIGS. 7A and 7B, the cutting of the substrate 510 through two laser scanning is exemplified, but cutting of the substrate 510 through three or more laser scanning operations may also be adopted/applied depending on the thickness of the substrate 510. When the substrate 510 is cut through a plurality of laser scanning operations, the focusing point of the laser beam LB in the subsequent laser scanning may be farther away from the mounting surface 111 of the mounting table 110 than the focusing point of the laser beam LB in the preceding laser scanning. In certain embodiments, depending on the thickness of the substrate 510, cutting of the substrate 510 may be completed through one laser scanning.

According to example embodiments of the inventive concept, the modification layer 530 may be more easily formed by irradiating the substrate 510 with the laser beam LB for forming cracks in the substrate 510 in a state in which the substrate 510 is forcibly modified/deformed into a concave form, and a propagation distance of cracks propagated from the modification layer 530 may be increased by the deformation/modification. As a result, the number of laser scanning operations required to complete the cutting of the substrate 510 may be reduced so that the cost may be reduced and productivity may be enhanced. Further, according to example embodiments of the inventive concept, because the substrate 510 may be cut using the laser beam LB having a relatively low power, semiconductor elements of the integrated circuit regions 512 may be prevented from being damaged by scattering of the laser beam LB that frequently occurs when using a laser beam LB having a high power.

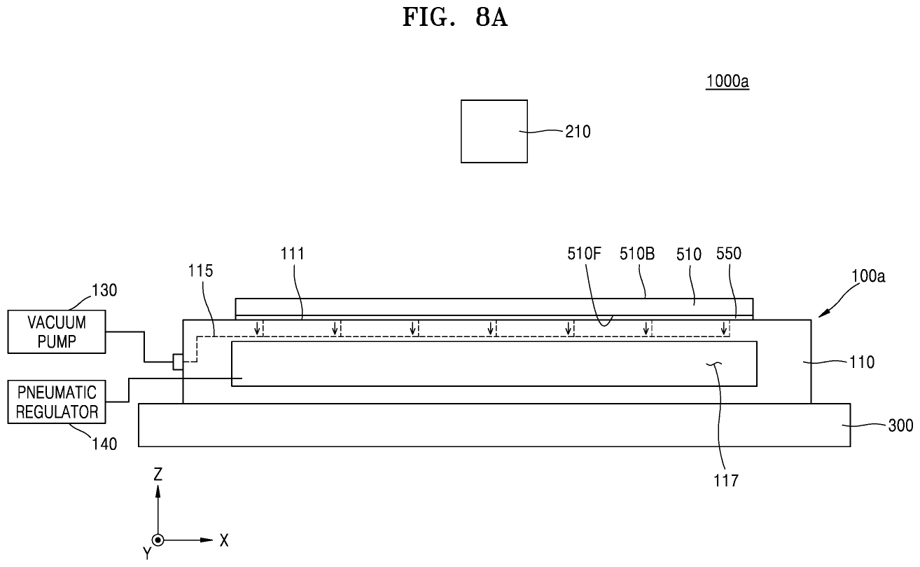

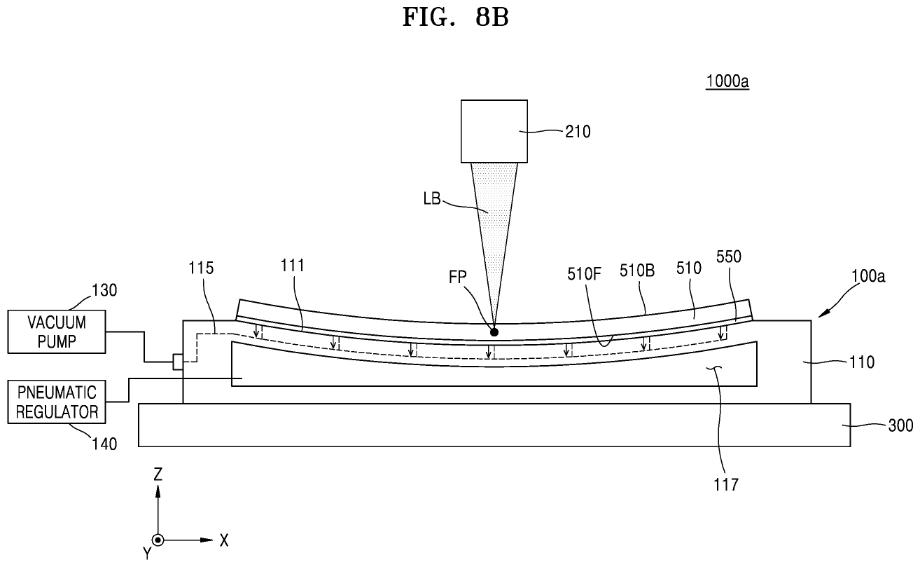

FIGS. 8A and 8B are views illustrating the configuration of a substrate processing apparatus 1000a according to example embodiments. Hereinafter, the substrate processing apparatuses 1000a of FIGS. 8A and 8B will be described based on a difference between the substrate processing apparatuses 1000 described with reference to FIG. 1.

Referring to FIGS. 8A and 8B, a chuck table 100a may adjust the shape and/or curvature of the mounting surface 111 of the mounting table 110. For example, the mounting surface 111 of the mounting table 110 may be configured to be switched from a flat first state as shown in FIG. 8A to a second state having a concave curved shape, as shown in FIG. 8B.

In example embodiments, the mounting table 110 may include a cavity 117 therein. The cavity 117 may be provided below the mounting surface 111 and vertically overlap the mounting surface 111, e.g., in a plan view. The chuck table 100a may include a pneumatic regulator 140 connected to the cavity 117. The pneumatic regulator 140 may adjust the pressure of the cavity 117 by injecting or discharging air into or from the cavity 117 of the mounting table 110. Depending on the pressure change of the cavity 117 of the mounting table 110, the shape of the mounting surface 111 may vary. For example, in order to change the mounting surface 111 of the mounting table 110 from the flat first state to the second state having a concave form, the pneumatic regulator 140 may discharge air from the cavity 117 to reduce the pressure of the cavity 117. As the pressure of the cavity 117 is lowered, the mounting surface 111 of the mounting table 110 may be modified/deformed into a concave form. In order to change the mounting surface 111 of the mounting table 110 from the second state having a concave form to the flat first state, the pneumatic regulator 140 may inject air into the cavity 117 to increase the pressure of the cavity 117. The mounting table 110 may include or be formed of a material capable of changing the shape of the mounting table 110 by an external force. For example, the mounting table 110 may include or be formed of a metal, silicon, rubber, ceramic, or a combination thereof.

In example embodiments, the pneumatic regulator 140 may include an air pump for injecting air into the cavity 117, an exhaust pump for discharging air from the cavity 117, and a flow rate control valve installed on an air flow path connected to the cavity 117.

In example embodiments, the chuck table 100a may be configured to vacuum adsorb the substrate 510 while the mounting surface 111 of the mounting table 110 is held in a flat state as shown in FIG. 8A. After the substrate 510 has been vacuumed to attach to the mounting surface 111 of the mounting table 110, the chuck table 100a may modify the mounting surface 111 of the mounting table 110 into a concave form. As the mounting surface 111 of the mounting table 110 is modified/deformed into a concave form from a flat form, the substrate 510 fixed to the mounting surface 111 of the mounting table 110 may also be concavely modified. Since the substrate 510 is modified after vacuum adsorption to the mounting table 110 is completed, the substrate 510 may be more stably modified.

While the inventive concept has been particularly shown and described with reference to embodiments thereof, it will be understood that various changes in form and details may be made therein without departing from the spirit and scope of the following claims.

1. A substrate processing apparatus comprising:
a chuck table comprising a mounting table having a mounting surface configured such that a substrate is mounted on the mounting surface, wherein the mounting surface is a curved surface; and
a laser supply head configured to irradiate the substrate mounted on the mounting table with a laser beam.

2. The substrate processing apparatus of claim 1, wherein the mounting surface comprises a concave surface.

3. The substrate processing apparatus of claim 1, wherein the mounting table comprises a plurality of vacuum channels extending from the mounting surface, and the substrate processing apparatus further comprises a vacuum pump configured to apply a vacuum pressure to the plurality of vacuum channels of the mounting table.

4. The substrate processing apparatus of claim 3, wherein the plurality of vacuum channels comprise at least one first vacuum channel extending from a central portion of the mounting surface of the mounting table and at least one second vacuum channel extending from an outer portion of the mounting surface of the mounting table, and the central portion of the mounting surface of the mounting table is configured to vacuum adsorb the central portion of the substrate, and the outer portion of the mounting surface of the mounting table is configured to vacuum adsorb the outer portion of the substrate.

5. The substrate processing apparatus of claim 1, wherein the chuck table is configured to forcibly modify the substrate so that the substrate has a curvature corresponding to a curvature of the mounting surface.

6. The substrate processing apparatus of claim 5, wherein the laser supply head is configured to focus a laser beam on a focusing point in the substrate when the substrate is modified by the chuck table.

7. The substrate processing apparatus of claim 6, wherein the laser supply head is configured to sequentially perform:
first laser scanning of irradiating a first focusing point in the substrate with the laser beam so that a first modification layer is formed in the substrate; and
second laser scanning of irradiating a second focusing point in the substrate with the laser beam so that a second modification layer is formed in the substrate, and
the first focusing point is closer to the mounting surface of the mounting table than the second focusing point.

8. The substrate processing apparatus of claim 7, further comprising a stage configured to move the mounting table in a direction perpendicular to an irradiation direction of the laser beam.

9. The substrate processing apparatus of claim 8, wherein the stage is configured to tilt the mounting table so that an incident angle of the laser beam to the mounting surface of the mounting table is adjusted.

10. The substrate processing apparatus of claim 1, wherein the chuck table is configured to adjust a curvature of the mounting surface of the mounting table.

11. The substrate processing apparatus of claim 10, wherein the mounting table comprises a cavity, and the substrate processing apparatus further comprises a pneumatic regulator configured to adjust pressure of the cavity by injecting or discharging air into or from the cavity.

12. The substrate processing apparatus of claim 11, wherein the pneumatic regulator is configured to adjust pressure of the cavity to modify the mounting surface of the mounting table between a flat first state and a second state in a concave form.

13. A substrate processing apparatus configured to perform a stealth dicing process on a substrate, the substrate processing apparatus comprising:
a chuck table comprising a mounting table having a mounting surface configured such that the substrate is vacuum adsorbed on the mounting surface, wherein the mounting surface comprises a curved surface, and configured such that the substrate is vacuum adsorbed to the mounting surface so that the substrate is modified to have a curvature corresponding to a curvature of the mounting surface; and
a laser supply head configured to irradiate the substrate attached to the mounting table with a laser beam.

14. The substrate processing apparatus of claim 13, wherein, in a cross-sectional view, the mounting surface of the mounting table extends in a curve form from one edge to another edge of the mounting surface of the mounting table.

15. The substrate processing apparatus of claim 14, wherein the mounting surface of the mounting table has a constant curvature.

16. The substrate processing apparatus of claim 13, wherein the mounting table comprises at least one first vacuum channel extending from a central portion of the mounting surface of the mounting table and at least one second vacuum channel extending from an outer portion of the mounting surface of the mounting table, and the mounting table is configured such that the central portion of the substrate is vacuum adsorbed to the central portion of the mounting surface of the mounting table and the outer portion of the substrate is vacuum adsorbed to the outer portion of the mounting surface of the mounting table.

17. The substrate processing apparatus of claim 13, wherein the laser supply head is configured to perform a plurality of laser scanning of irradiating different focusing points in the substrate with the laser beam, and a focusing point of subsequent laser scanning in the plurality of laser scanning is farther from the mounting surface of the mounting table than a focusing point of preceding laser scanning.

18. The substrate processing apparatus of claim 13, wherein the mounting table comprises a cavity, and the mounting table is configured such that a curvature of the mounting surface of the mounting table varies according to pressure of the cavity.

19. A substrate processing apparatus configured to perform a stealth dicing process on a substrate, the substrate processing apparatus comprising:
a chuck table comprising a mounting table and a vacuum pump, wherein the mounting table comprises a mounting surface configured such that the substrate is vacuum adsorbed on the mounting surface and vacuum channels extending from the mounting surface and the vacuum pump is connected to the vacuum channels of the mounting table;
a stage configured to move the mounting table; and
a laser supply head configured to irradiate the substrate attached to the mounting table with a laser beam,
wherein the mounting surface of the mounting table comprises a concave curved surface, and the chuck table modifies the substrate so that the substrate has a curvature corresponding to a curvature of the mounting surface of the mounting table, and the laser supply head is configured to irradiate a focusing point in the substrate modified by the chuck table with the laser beam.

20. The substrate processing apparatus of claim 19, wherein the mounting table comprises a cavity provided below the mounting surface, and the substrate processing apparatus further comprises a pneumatic regulator configured to adjust pressure of the cavity by injecting or discharging air into or from the cavity, and the mounting table is configured such that the curvature of the mounting surface of the mounting table varies depending on pressure of the cavity.

21-26. (canceled)
